(19) United States
(12) Patent Application Publication
(10) Pub. No.: US 2003/0100235 A1
(43) Pub. Date: May 29, 2003

(54) Articles having low reflectance conductive coatings with conductive component outermost

(75) Inventor: Wilfred C. Kittler JR., Santa Rosa, CA (US)

Correspondence Address: Thomas R. Juettner, Greer, Burns & Crain, Ltd., Suite 2500, 300 South Wacker Drive, Chicago, IL, 60606, US

(73) Assignee: N.V. BEKAERT S.A.

(21) Appl. No.: 10/021,135

(22) Filed: Nov. 29, 2001

(51) Int. Cl. B32B 5/02; B32B 27/04; B32B 27/12; C23C 16/06; C23C 16/00; C23C 16/40

(52) U.S. Cl. 442/117; 442/110; 427/255.36; 427/255.37; 427/255.32; 427/255.28

(57) ABSTRACT

The visible light reflectance of polymeric substrates coated with conductive oxides is minimized over a broad region of the visible light spectrum by alternating layers of materials of high and low refractive index interposed between the substrate and the conductive oxide. The conductive oxide is outermost to permit direct electrical contact to be made. Visible light reflectance is 10% or less and visible light transmittance is 90% or more over a broad region of the spectrum.

### FIELD OF THE INVENTION

The invention relates to electrical conductors comprised of a substrate bearing a conductive coating and having the conductive component of the coating outermost so that direct electrical contact can be made. The invention relates, more particularly, to electrical conductors comprised of a transparent polymeric substrate bearing a transparent conductive coating having the conductive component outermost and having high visible light transmittance and low visible light reflectance.

### BACKGROUND OF THE INVENTION

Transparent conductive oxides (“TCOs”), for example, indium oxide, tin oxide, and their mixtures, as well as others such as doped zinc oxide, are applied to polymeric substrate materials, for example, polyethylene terephthalate (“PET”) and other plastics for use as electrical conductors in a variety of electronic devices such as transparent membrane switches, touch panels, electroluminescent lamps, and the like. The TCO is typically applied to the substrate, and then used in air as an element of a switch such as a touch panel, or laminated to a medium such as an adhesive, an electroluminescent phosphor-binder, or a display medium such as a liquid crystal.

The transparent conductors typically have an index of refraction greater than 1.9 over the visible spectrum. In contrast, typical plastic substrate materials have optical indices ranging from about 1.35 to about 1.7, and air has a refractive index of 1.0. Since the refractive index of the TCO is higher than either the substrate or a typical lamination medium or air, reflectance from the substrate is increased. This increased reflectance is undesirable because it decreases the contrast and readability of the display and reduces the transmittance through the assembly, and may make devices unusable under high ambient illumination.

To overcome this problem, it is known to add additional coating layers, which may not be electrically conductive, to “anti-reflect” or “index match” the TCO to the substrate and to the medium. However, in the case of many electrical devices, such as transparent switches, it is necessary to make direct contact to the conductive TCO. Thus, the high index TCO must be the outermost layer of the multi-layer film. This is not a typical construct for anti-reflective coatings.

It has previously been proposed to use a film construction of substrate/titanium dioxide/silicon dioxide/indium tin oxide to achieve high peak transmittance. However, although these coatings have low reflectance, there remains noticeable and objectionable reflected color. The color can be adjusted from blue through purple to gold, but is evident and objectionable, particularly for displays which are read by reflected light. Further, if the coatings are tuned for peak visual transmittance, the transmittance for blue light is decreased, which distorts the color of the display. Tuning the coatings for near transmittance neutrality is possible, but this results in a decreased overall transmittance and an objectionable high intensity yellow gold reflectance.

There is a need for a conductive coating with the conductive component outermost and having both high visible light transmittance and low visible light reflectance.

### OBJECTS OF THE INVENTION

It is a prime object of the invention to provide a transparent conductive coating adapted to be exposed for direct electrical contact and having high visible light transmittance (“VLT”) and low visible light reflectance (“VLR”).

It is also an object of the invention to provide a transparent conductive coating having a broadened range of reduced reflectance over the visible light spectrum.

A further object of the invention is to provide a substrate film coated with an outermost transparent conductive coating having low VLR and high VLT that is economical to manufacture.

### SUMMARY OF THE INVENTION

In accordance with the invention, a transparent film of plastic substrate material, such as PET, is coated with a layer of material having a high index of refraction, i.e., a refractive index equal to or greater than that of the substrate, a layer of material having a low index of refraction, i.e., a refractive index less than that of the material of high refractive index, a second layer of material having a high index of refraction and a layer of a transparent conductive oxide.

In some film constructs, it may be necessary, or at least advisable, to include a second layer of low refractive index material over the second layer of material of high refractive index and beneath the layer of transparent conductive oxide.

The thickness of the layer of transparent conductive oxide is variable to impart the requisite electrical conductivity to the article as required for different applications. The thicknesses of the layers of the materials of high and low refractive index are selected and optimized relative to the thickness of the TCO layer to produce a broad region of minimum reflectance over the energy spectrum of visible light.

The coated film may be economically produced by passing a web of substrate film through a coater having multiple coating stations for sequential deposition of the coating materials.

The foregoing and other objects and advantages of the invention will become apparent to those of reasonable skill in the art from the following detailed description, as considered in conjunction with the accompanying drawings.

### BRIEF DESCRIPTION OF THE DRAWINGS

FIG. 1 is a fragmentary cross-section, on an enlarged scale, of a first embodiment of the coated film of the invention;

FIG. 2 is a graph depicting the percent visible light transmittance and the percent visible light reflectance of the coated film illustrated in FIG. 1;

FIG. 3 is a fragmentary cross-section, on an enlarged scale, of a second embodiment of the coated film of the invention; and,

FIG. 4 is a graph depicting the percent visible light transmittance and the percent visible light reflectance of the coated film illustrated in FIG. 3.

### DETAILED DESCRIPTION OF PREFERRED EMBODIMENTS

The following is a detailed description of certain embodiments of the invention presently deemed by the inventor to be the best mode of carrying out his invention.

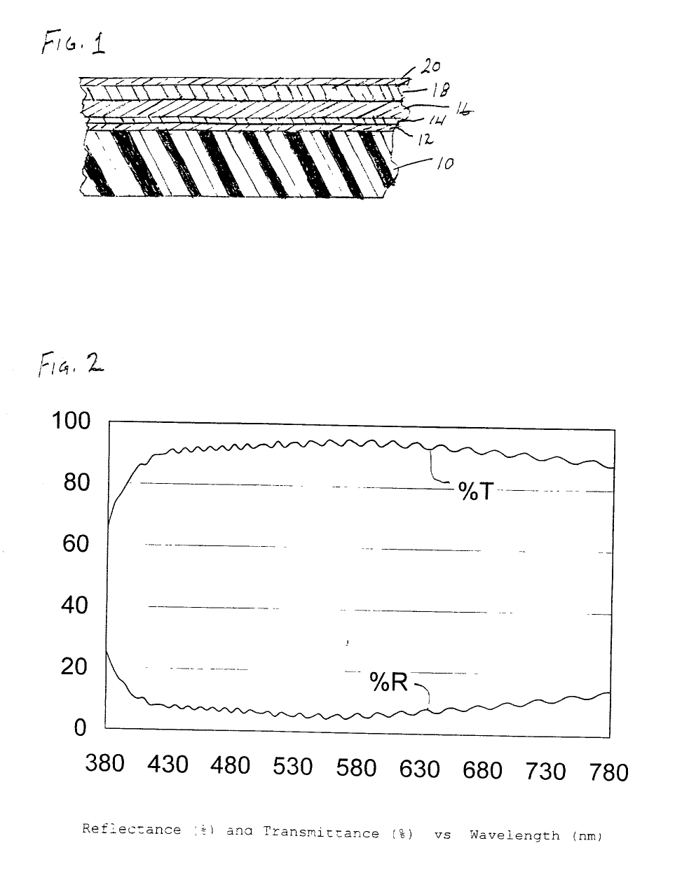

FIG. 1 illustrates a conductive film intended to have its conductive surface exposed to air for use, for example, in typical touch panel applications. For such applications, the film is preferably comprised of a transparent polymeric substrate 10, a first layer 12 of a material having a high index of refraction, a first layer 14 of material having a low index of refraction, a second layer 16 of material having a high index of refraction, a second layer 18 of a material having a low index of refraction, and an outermost layer 20 of transparent conductive oxide (TCO).

The substrate 10 preferably comprises a flexible polymeric film, such as a film of polyethylene terephthalate (PET) or equivalent having a thickness of from about 1/2 to about 10 mils (3 and 7 mils are typical) and a refractive index in the order of about 1.5 to 1.67 over the energy spectrum of visible light, i.e., from about 380 to about 780 nanometers (nm).

The two layers 12 and 16 of a material having a high index of refraction should have an index of refraction at least equal to and preferably greater than that of the substrate. The layers may be formed of the same material or different materials, but are preferably formed of the same material. To facilitate production of the coating by sputter deposition, the preferred material for the layers 12 and 16 is titanium dioxide (TiO₂) or equivalent. The refractive index of sputter deposited TiO₂ is from about 2.2 to about 2.7 over the visible light spectrum.

The two layers 14 and 18 of a material having a low index of refraction must have an index of refraction less than that of the layers 12 and 16. The layers of low index material may be formed of the same material or different materials but are preferably formed of the same material. To facilitate production by sputter deposition, the preferred material for the low index layers is silicon dioxide (SiO₂) or equivalent. The refractive index of sputter deposited SiO₂ is from about 1.46 to about 1.55 over the visible light spectrum.

The TCO layer 20 may be selected from the group of known transparent conductive oxides, such as indium oxide, tin oxide, indium tin oxide, etc., but is preferably indium tin oxide (ITO), which has a nominal refractive index over the visible spectrum of about 2.0. The thickness of the layer 20 is dictated by the electrical conductivity required of the coated article for the application to which it is to be applied, and the thickness of the layer 20 in turn dictates the design of the index matching, reflection reducing high/low layers 12, 14, 16 and 18. These layers and their thicknesses are chosen and optimized to produce a broad region of minimum reflection over the visible light spectrum.

For typical touch panel applications, where the layer 20 is exposed to air, the conductive layer should have a surface resistivity in the order of about 400 ohms per square. This requires a layer of ITO having a thickness of about 20 nm.

Customization of the design is accomplished by entering a starting design in a thin film computer-design program, such as the “TFCalc” (TM) program, and using the numerical calculation and optimization functions of the program to refine the starting design layer thicknesses for best optical performance, holding the thickness of the TCO layer constant, in this case at 20 nm. A nominal design for typical touch panel applications is as follows:

| Substrate or Layer | Material |
|---|---|
| Substrate 10 | PET-7 mil |
| Layer 12 | 26 nm. TiO₂ |
| Layer 14 | 19.5 nm. SiO₂ |
| Layer 16 | 16 nm. TiO₂ |
| Layer 18 | 50 nm. SiO₂ |
| Layer 20 | 20 nm. ITO |

Optionally, the lower surface of substrate 10 may be coated with a layer of hardcoat material.

FIG. 2 graphically portrays the measured visible light transmittance and visible light reflectance of the coated article above described. As shown, over the energy range of 430 to 730 nm., VLT is greater than 90% and VLR is less than 10%¹. The invention thus provides touch panels and similar conductive articles having the conductive component outermost and having high visible light transmittance with extremely little if any observable reflectance. ¹ The graph depicts the overall reflectance of the article, i.e., the reflectance of both the coated and uncoated sides of the substrate. Subtracting the approximate six percent (6%) reflectance of the uncoated side yields an extremely low reflectance for the coated side.

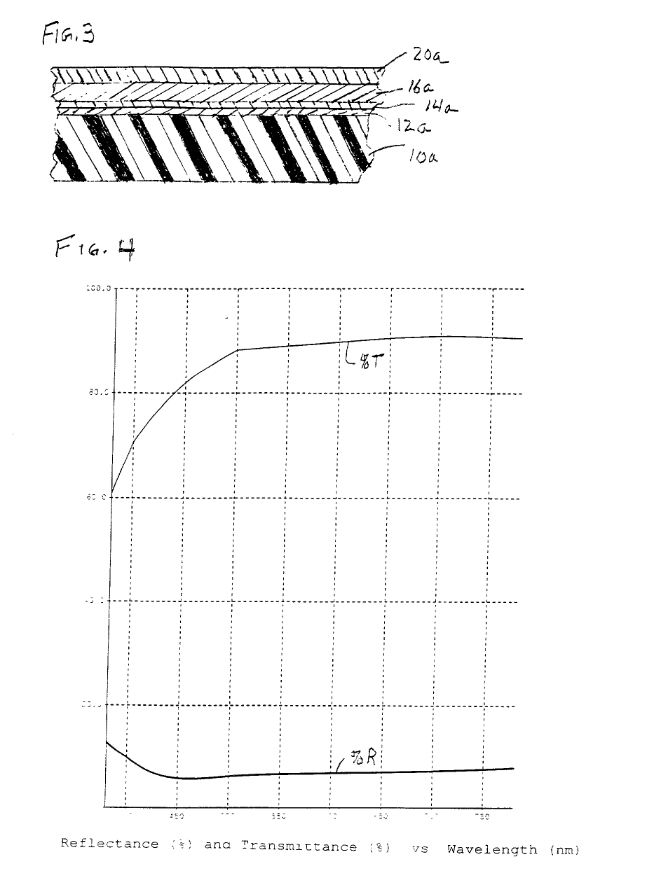

FIG. 3 illustrates a second embodiment of the invention adapted for a different purpose, namely, a conductive article intended and adapted to have its TCO layer adhered to a display or lamination medium that has a nominal index of refraction of about 1.52. The article is comprised of a substrate 10a, a layer 12a of a material having a high index of refraction, a layer 14a of a material having a low index of refraction, a layer 16a of a material having a high index of refraction, and a layer 20a of TCO. For reasons explained below, a second layer 18 of low refractive index is not required in this design.

For the described application, the layer 20a of TCO is preferably ITO at a nominal thickness of 110 nm. and a surface resistivity of 60 ohms per square. The design and thicknesses of the index matching layers, i.e., the alternating layers of materials of high and low refractive index, are again, as above described, chosen and optimized via a thin film computer-design program to produce a broad region of minimum reflectance over the visible light energy range. A nominal design is as follows:

| Substrate or Layer | Material |
|---|---|
| Substrate 10a | PET-7 mil |
| Layer 12a | 15.6 nm. TiO₂ |
| Layer 14a | 37 nm. SiO₂ |
| Layer 16a | 21.7 nm. TiO₂ |
| Layer 20a | 110 nm. ITO |

Due to the facts that the layer 20a is quite thick and is intended to be adhered to a medium of refractive index 1.52 (rather than being exposed to air at index 1.0), design optimization removes the need for a second layer of material of low refractive index, thus simplifying the coated article.

FIG. 4 is a computer-generated graph of the design performance of the embodiment of the invention shown in FIG. 3. In the visible light spectrum of 450-750 nm, the graph illustrates that VLT is very high and that VLR is less than 10%. The coated article thus provides for high visible light transmittance and virtually no observable reflectance.

Many similar designs are possible, each being optimized for the optical exit medium and the thickness of TCO required for the application. These designs have the further advantage that since the only conductive layer is the top TCO coating, the TCO can be etched or patterned and the remaining dielectric layers will still continue to provide a barrier to diffusion through or from the substrate to the surface of the coating.

Results achieved by practice of the invention are improved optical performance in applications requiring high optical transmittance and readability in high ambient light conditions, e.g., outdoor displays, where direct contact with an electrically conductive coating is needed.

Also, the coated articles of the invention can be produced conveniently and economically on continuous webs of substrate film by sputter deposition techniques, especially magnetron sputtering in apparatus having a plurality of sputtering stations, e.g., four or five stations, for sequential aplication to the substrate of the materials of high and low reflective index and the TCO. See, as a representative example, the multi-station sputtering apparatus illustrated in FIG. 7 of U.S. reissue Pat. No. Re. 36,308, reissued Sep. 21, 1999.

The objects and advantages of the invention have now been shown to be attained in a convenient, practical, economical and facile manner.

While certain preferred embodiments of the invention have been herein illustrated and described, it is to be appreciated that various changes, rearrangements and modifications may be made therein without departing from the scope of the invention as defined by the appended claims.

What is claimed is:

1. A conductive article of manufacture having its conductive component outermost comprising
a polymeric substrate,
a first layer of material of high refractive index deposited on the substrate,
a layer of material of low refractive index deposited on said first layer of material of high refractive index,
a second layer of material of high refractive index deposited on said layer of material of low refractive index, and
a layer of conductive material overlying said second layer of material of high refractive index, said conductive layer being outermost for direct electrical contact,
said material of high refractive index having an index of refraction equal to or greater than the index of refraction of said substrate, and said material of low refractive index having an index of refraction less than the index of refraction of said material of high refractive index,
said layers of materials of high and low refractive index being effective to substantially optically match the refractive indices of said layer of conductive material and said substrate and to minimize reflection of the article over the visible light spectrum.

2. A conductive article as set forth in claim 1 wherein said layers of material of high refractive index comprise TiO₂ and said layer of material of low refractive index comprises SiO₂.

3. A conductive article as set forth in claim 2 wherein said layer of conductive material comprises a transparent conductive oxide.

4. A conductive article as set forth in claim 3, where the article is adapted to be adhered at the surface of its conductive layer to a display or lamination medium.

5. A conductive article as set forth in claim 4 wherein said layer of conductive oxide has a thickness of about 110 nm and a surface resistivity in the order of about 60 ohms per square, said first layer of material of high refractive index has a thickness in the order of about 15-16 nm, said layer of material of low refractive index has a thickness in the order of about 36-38 nm, and said second layer of material of high refractive index has a thickness of about 21-22 nm, and said article has a reflectance of less than 10% over a broad region of the visible light spectrum.

6. A conductive article as set forth in claim 1 including a second layer of material of low refractive index deposited on said second layer of material of high refractive index and underlying said layer of conductive material.

7. A conductive article as set forth in claim 6 wherein said layers of material of high refractive index comprise TiO₂, said layers of material of low refractive index comprise SiO₂, and said layer of conductive material comprises a transparent conductive oxide.

8. A conductive article as set forth in claim 7 wherein the article is adapted to be used with its conductive layer exposed to air.

9. A conductive article as set forth in claim 8 wherein said layer of conductive oxide has a thickness of about 20 nm and a surface resistivity in the order of about 400 ohms per square, said first layer of material of high refractive index has a thickness in the order of about 26 nm, the first-named layer of material of low refractive index has a thickness in the order of about 19-20 nm, said second layer of material of high refractive index has a thickness in the order of about 61 nm, the second layer of material of low refractive index has a thickness in the order of about 61 nm, and said article has a reflectance of less than 10% over a broad region of the visible light spectrum.

10. A method of producing an electrically conductive article having its conductive component outermost and having reduced reflectance over a broad region of the visible light spectrum, comprising the steps of
providing a polymeric substrate,
depositing on the substrate a first layer of material of high refractive index,
depositing on the first layer of material of high refractive index a layer of material of low refractive index,
depositing on the layer of material of low refractive index a second layer of material of high refractive index, and
depositing on the second layer of material of high refractive index an outermost layer of a transparent conductive oxide,
the alternating layers of materials of high and low refractive index being effective to minimize reflectance and enhance transmittance of the article over a broad region of the visible light spectrum.

11. A method as set forth in claim 10 wherein the alternating layers of materials of high and low refractive index are effective to provide a transparent conductive article having visible light reflectance of about 10% or less and visible light transmittance of about 90% or more.

12. A method as set forth in claim 10 including the performance, after the step of depositing the second layer of material of high refractive index and before the step of depositing the layer of a transparent conductive oxide, of the step of depositing on the second layer of material of high refractive index a second layer of material of low refractive index.

13. A method as set forth in claim 10 where the article is adapted to be adhered at its outermost conductive layer to a display or lamination medium and the method includes the steps of:
depositing a relatively thin first layer of the material of high refractive index,
depositing a relatively thick layer of the material of low refractive index,
depositing a relatively thin second layer of the material of high refractive index, and
depositing a much thicker layer of the transparent conductive oxide.

14. A method as set forth in claim 10 wherein the article is adapted to be adhered at its outermost conductive layer to a display or lamination medium and the method includes the steps of:
depositing on the substrate a first layer of TiO₂ having a thickness in the order of about 15-16 nm,
depositing on the first layer of TiO₂ a layer of SiO₂ having a thickness in the order of about 36-38 nm,
depositing on the layer of SiO₂ a second layer of TiO₂ having a thickness in the order of about 21-22 nm, and
depositing on the second layer of TiO₂ a layer of indium oxide or tin oxide or a indium tin oxide having a thickness in the order of about 110 nm and a surface resistivity in the order of about 60 ohms per square.

15. A method as set forth in claim 14 wherein the alternating layers of high and low refractive index are effective to provide a transparent conductive article having visible light reflectance of about 10% or less and visible light transmittance of about 90% or more.

16. A method as set forth in claim 12 wherein the article is adapted to be used with its outermost conductive layer openly exposed and the method includes the steps of:
depositing a relatively thin first layer of the material of high refractive index,
depositing a relatively thin first layer of the material of low refractive index,
depositing a relatively thick second layer of the material of high refractive index,
depositing a relatively thick second layer of the material of low refractive index, and
depositing a relatively thin layer of the transparent conductive oxide.

17. A method as set forth in claim 12 wherein the article is adapted to be used with its outermost conductive layer openly exposed, and the method includes the steps of:
depositing on the substrate a first layer of TiO₂ having a thickness in the order of about 26 nm,
depositing on the first layer of TiO₂ a first layer of SiO₂ having a thickness in the order of about 19-20 nm,
depositing on the first layer of SiO₂, a second layer of TiO₂ having a thickness in the order of about 61 nm,
depositing on the second layer of TiO₂ a second layer of SiO₂ having a thick ness in the order of about 61 nm, and
depositing on the second layer of SiO₂ a layer of indium oxide or tin oxide or indium tin oxide having a thickness in the order of about 20 nm and a surface resistivity in the order of about 400 ohms per square.

18. A method as set forth in claim 17 wherein the alternating layers of materials of high and low refractive index are effective to provide a transparent conductive article having visible light reflectance of about 10% or less and visible light transmittance of about 90% or more.

19. A method as set forth in claim 10 wherein the steps of depositing are performed sequentially by sputter deposition.

20. A method as set forth in claim 19 wherein the steps of depositing are performed sequentially in a sputtering chamber having a plurality of sputtering stations.
